(19) United States
(12) Patent Application Publication
(10) Pub. No.: US 2026/0016519 A1
(43) Pub. Date: Jan. 15, 2026

(54) HIGH-RESOLUTION TIME-FREQUENCY ANALYSIS FOR NONSTATIONARY SIGNALS

(71) Applicant: HAMAD BIN KHALIFA UNIVERSITY, Doha (QA)

(72) Inventors: Nisreen Said Amer, Doha (QA); Samir Brahim Belhaouari, Doha (QA)

(21) Appl. No.: 19/265,224

(22) Filed: Jul. 10, 2025

Related U.S. Application Data
(60) Provisional application No. 63/669,778, filed on Jul. 11, 2024.

(51) Int. Cl. G01R 23/16; G06F 17/14

(52) U.S. Cl. CPC G01R 23/16; G06F 17/142

(57) ABSTRACT

Example systems, methods, and apparatus are disclosed herein for a high-resolution time-frequency analysis for nonstationary signals. Time-frequency distributions (TFDs) are essential tools for analyzing nonstationary signals in various applications. The proposed technology, Zoom, a novel time-frequency distribution (TFD) designed to enhance the resolution and reduce cross-term interference. The performance of the proposed TFD is rigorously evaluated by studying its behavior across different smoothing values, allowing for a detailed analysis of its time-frequency localization capabilities. To quantify its effectiveness, the proposed technology computes several performance metrics, including time-frequency concentration and cross-term reduction.

### CROSS-REFERENCE TO RELATED APPLICATION

The present disclosure claims priority to U.S. Provisional Patent Application 63/669,778 having a filing date of Jul. 11, 2024, the entirety of which is incorporated herein.

### BACKGROUND

The analysis of nonstationary signals exhibiting time-varying spectral content is crucial in numerous real-world applications. These signals often contain multiple components that require sophisticated analytical techniques for precise interpretation. Time-frequency distributions (TFDs) provide an effective solution by mapping one-dimensional signals onto a two-dimensional time-frequency plane, allowing for a detailed examination of their temporal and spectral properties.

Quadratic TFDs, also known as kernel-based TFDs, are particularly noteworthy due to their capability to balance time and frequency resolution while mitigating interference patterns. These distributions employ a two-dimensional kernel function to achieve this balance. Among them, kernels with compact support have demonstrated significant promise, offering enhanced auto-term resolution and effective cross-term suppression.

However, implementing Gaussian kernels in these TFDs presents challenges, such as information loss and increased computational demands due to their infinite support. To overcome these issues, recent advancements have introduced compact support kernels, such as the separable KCS (SKCS) and polynomial KCS (PKCS), which maintain the advantageous properties of Gaussian kernels while improving efficiency and accuracy.

One well-known TFD is the Zhao-Atlas-Marks Distribution (ZAMD), which utilizes a cone-shaped kernel to improve the representation of nonstationary signals. The ZAMD is designed to suppress cross-terms while maintaining good time-frequency localization. It has effectively managed signals with varying frequency components, providing a clearer and more interpretable time-frequency representation than traditional methods.

Another significant TFD is the Choi-Williams Distribution (CWD), which employs an exponential kernel to reduce interference terms. The CWD is known for providing high resolution in both time and frequency domains while minimizing cross-term interference. This makes it popular for analyzing complex signals with multiple components and varying frequencies.

The Wigner-Ville Distribution (WVD) is renowned for its high-resolution representation but suffers from significant cross-term interference, making it less suitable for multicomponent signals. The Spectrogram, derived from the Short-Time Fourier Transform (STFT), offers a more straightforward and interpretable approach but involves a tradeoff between time and frequency resolution. Methods like the Born-Jordan Distribution (BJD), Cheriet-Belouchrani (CB) Kernel TFD, PKCS, SKCS, Zhao-Atlas-Marks Distribution (ZAMD), and CWD attempt to balance this tradeoff and suppress cross-terms, each with varying degrees of success.

Despite the advancements offered by these methods, there remains a need for improved techniques that can deliver high-resolution time-frequency representations with minimal noise and interference.

### SUMMARY

Example systems, methods, and apparatus are disclosed herein for a high-resolution time-frequency analysis for nonstationary signals. The proposed technology, Zoom, is a novel method combining windowed Fast Fourier Transform (FFT) and harmonic suppression to achieve high-resolution time-frequency analysis. This method dynamically adjusts thresholds to retain significant components while minimizing noise, providing a clearer and more detailed time-frequency representation.

In light of the disclosure herein, and without limiting the scope of the invention in any way, in an aspect of the present disclosure, which may be combined with any other aspect listed herein unless specified otherwise, the present disclosure includes a high-resolution time-frequency analysis for nonstationary signals comprising a signal-windowed Fast Fourier Transform; and a harmonic suppression.

In another aspect of the present disclosure, which may be combined with any other aspect listed herein unless specified otherwise, the signal-windowed Fast Fourier Transform includes a Hamming window function.

In another aspect of the present disclosure, which may be combined with any other aspect listed herein unless specified otherwise, the time-frequency analysis includes spectral smoothing.

In another aspect of the present disclosure, which may be combined with any other aspect listed herein unless specified otherwise, the spectral smoothing is recursive.

In another aspect of the present disclosure, which may be combined with any other aspect listed herein unless specified otherwise, the time-frequency analysis includes convolution.

In another aspect of the present disclosure, which may be combined with any other aspect listed herein unless specified otherwise, the convolution includes a Gaussian kernel to smooth and enhance the nonstationary signal.

In another aspect of the present disclosure, which may be combined with any other aspect listed herein unless specified otherwise, the time-frequency analysis includes minimum smart thresholding.

In another aspect of the present disclosure, which may be combined with any other aspect listed herein unless specified otherwise, the time-frequency analysis includes a reconstruction of the time-frequency analysis by combining processed spectra.

In another aspect of the present disclosure, which may be combined with any other aspect listed herein unless specified otherwise, the present disclosure includes a method of using a high-resolution time-frequency analysis for nonstationary signals a signal-windowed Fast Fourier Transform; and a harmonic suppression.

In another aspect of the present disclosure, which may be combined with any other aspect listed herein unless specified otherwise, performing the signal-windowed Fast Fourier Transform includes performing a Hamming window function.

In another aspect of the present disclosure, which may be combined with any other aspect listed herein unless specified otherwise, the method further includes performing spectral smoothing.

In another aspect of the present disclosure, which may be combined with any other aspect listed herein unless specified otherwise, the spectral smoothing is recursive.

In another aspect of the present disclosure, which may be combined with any other aspect listed herein unless specified otherwise, the method further includes performing convolution.

In another aspect of the present disclosure, which may be combined with any other aspect listed herein unless specified otherwise, performing convolution includes utilizing a Gaussian kernel to smooth and enhance the nonstationary signal.

In another aspect of the present disclosure, which may be combined with any other aspect listed herein unless specified otherwise, the method further includes performing minimum smart thresholding.

In another aspect of the present disclosure, which may be combined with any other aspect listed herein unless specified otherwise, the method further includes reconstructing the time-frequency analysis by combining processed spectra.

In light of the present disclosure and the above aspects, it is therefore an advantage of the present disclosure to provide users with a high-resolution time-frequency analysis for nonstationary signals and method for using a high-resolution time-frequency analysis for nonstationary signals.

Additional features and advantages are described in, and will be apparent from, the following Detailed Description. The features and advantages described herein are not all-inclusive and, in particular, many additional features and advantages will be apparent to one of ordinary skill in the art in view of the figures and description. In addition, any particular embodiment does not have to have all of the advantages listed herein and it is expressly contemplated to claim individual advantageous embodiments separately. Moreover, it should be noted that the language used in the specification has been selected principally for readability and instructional purposes, and not to limit the scope of the inventive subject matter.

### BRIEF DESCRIPTION OF THE DRAWINGS

The patent or application file contains at least one drawing executed in color. Copies of this patent or patent application publication with color drawing(s) will be provided by the office upon request and payment of the necessary fee.

FIG. 1 illustrates performance against smart minimum values, according to an example embodiment of the present disclosure.

FIG. 2 illustrates performance against smoothing values, according to an example embodiment of the present disclosure.

FIG. 3A illustrates a graph of a simulated chirp signal with a smoothing parameter of 0.5, according to an example embodiment of the present disclosure.

FIG. 3B illustrates a graph of the proposed technology TFD applied on a chirp signal with a smoothing parameter of 0.5 and a smart minimum value of 0.1, according to an example embodiment of the present disclosure.

FIG. 3C illustrates a graph of the proposed technology TFD applied on a chirp signal with a smoothing parameter of 0.5 and a smart minimum value of 0.6, according to an example embodiment of the present disclosure.

FIG. 3D illustrates a graph of the proposed technology TFD applied on a chirp signal with a smoothing parameter of 0.5 and a smart minimum value of 0.995, according to an example embodiment of the present disclosure.

FIG. 4A illustrates a graph of a simulated chirp signal with a smoothing parameter of 0.5, according to an example embodiment of the present disclosure.

FIG. 4B illustrates a graph of the proposed technology TFD applied on a chirp signal with a smoothing parameter of 0.1 and a smart minimum value of 0.95, according to an example embodiment of the present disclosure.

FIG. 4C illustrates a graph of the proposed technology TFD applied on a chirp signal with a smoothing parameter of 0.6 and a smart minimum value of 0.95, according to an example embodiment of the present disclosure.

FIG. 4D illustrates a graph of the proposed technology TFD applied on a chirp signal with a smoothing parameter of 0.95 and a smart minimum value of 0.95, according to an example embodiment of the present disclosure.

FIG. 5A illustrates graphs of the proposed technology TFD applied on a linear function, according to an example embodiment of the present disclosure.

FIG. 5B illustrates graphs of the proposed technology TFD applied on a first mixed function, according to an example embodiment of the present disclosure.

FIG. 5C illustrates graphs of the proposed technology TFD applied on a second mixed function, according to an example embodiment of the present disclosure.

FIG. 5D illustrates graphs of the proposed technology TFD applied on a sawtooth function, according to an example embodiment of the present disclosure.

FIG. 5E illustrates graphs of the proposed technology TFD applied on a sine function, according to an example embodiment of the present disclosure.

FIG. 5F illustrates graphs of the proposed technology TFD applied on a step function, according to an example embodiment of the present disclosure.

FIG. 6A illustrates a graph of the proposed technology TFD applied on a chirp signal, according to an example embodiment of the present disclosure.

FIG. 6B illustrates a graph of the proposed technology TFD presented on a Wigner-Bille Distribution, according to an example embodiment of the present disclosure.

FIG. 6C illustrates a graph of the proposed technology TFD presented on a spectrogram, according to an example embodiment of the present disclosure.

FIG. 6D illustrates a graph of the proposed technology TFD presented on a Born-Jordan Distribution, according to an example embodiment of the present disclosure.

FIG. 6E illustrates a graph of the proposed technology TFD presented on a Cheriet-Belouchrani Kernel, according to an example embodiment of the present disclosure.

FIG. 6F illustrates a graph of the proposed technology TFD presented on a Polynomial Compact Support Kernel, according to an example embodiment of the present disclosure.

FIG. 6G illustrates a graph of the proposed technology TFD presented on a Separable Compact Support Kernel, according to an example embodiment of the present disclosure.

FIG. 6H illustrates a graph of the proposed technology TFD presented on a Zhao-Atlas-Marks Distribution, according to an example embodiment of the present disclosure.

FIG. 6I illustrates a graph of the proposed technology TFD presented on a Choi-Williams Distribution, according to an example embodiment of the present disclosure.

FIG. 6J illustrates a graph of the proposed technology TFD, according to an example embodiment of the present disclosure.

### DETAILED DESCRIPTION

Methods, systems, and apparatus are disclosed herein for a high-resolution time-frequency analysis for nonstationary signals.

While the example methods, apparatus, and systems are disclosed herein for a high-resolution time-frequency analysis for nonstationary signals, it should be appreciated that the methods, apparatus, and systems may be operable for other applications.

In recent years, several innovative approaches have been developed to enhance the performance of TFDs. For instance, adaptive kernel-based methods have been proposed to tailor the kernel function to the specific characteristics of the analyzed signal. The Adaptive Optimal Kernel (AOK) design optimizes the kernel by maximizing the concentration of energy around the instantaneous frequency components of the signal. Another notable method involves using synchro-squeezing transforms, which offer improved resolution and concentration of energy in the time-frequency plane by reassigning the signal's energy based on its instantaneous frequency.

Data-driven approaches have also emerged, leveraging machine learning techniques to design TFD kernels adaptively. These methods, such as the use of convolutional neural networks for time-frequency analysis, have shown great potential in enhancing the resolution and reducing the interference of TFDs.

Moreover, various studies have focused on optimizing the kernel functions for specific signal classes to enhance the performance of TFDs. For example, using multidirectional distributions for piecewise-LFM signals requires precise signal direction estimation but performs poorly with nonlinear LFM signals. Other adaptive methods, such as the locally adaptive directional time-frequency distributions, provide better performance in multicomponent instantaneous frequency estimation.

Recent advancements in time-frequency distributions (TFDs) have significantly enhanced the analysis of nonstationary signals across various domains. Literature developed a time-frequency and statistical inference-based technique for interference detection in GNSS receivers, combining TFDs with statistical analysis to detect and mitigate interference, ensuring reliable signal reception. Literature introduced a novel characterization method of impedance cardiography signals using TFDs, demonstrating improved diagnostic capabilities in identifying cardiac conditions through high-resolution TFDs. Literature presented a spatial time-frequency distribution technique for direction-of-arrival (DOA) estimation of weak nonstationary signals, incorporating spatial information to significantly enhance the accuracy of DOA estimation by addressing cross-term interference. Literature proposed an adaptive instantaneous frequency estimation method for multicomponent signals based on linear time-frequency transforms, which dynamically adjusts TFD parameters to optimize the representation of each signal component, providing accurate instantaneous frequency estimates. Literature introduced an amplitude and frequency-preserving S transform for geoscience and remote sensing applications, maintaining the amplitude and frequency characteristics of the original signal and offering a reliable tool for analyzing nonstationary signals in geophysical data. These advancements collectively highlight the evolving capabilities of TFDs in enhancing signal analysis through improved resolution, interference mitigation, and adaptive techniques.

The Wigner-Ville Distribution (WVD) is one of the most widely used TFDs for analyzing nonstationary signals. It provides a high-resolution representation of the signal in the time-frequency domain but is known for producing cross-terms, which can obscure the interpretation of the signal components. The WVD is defined as:

$$W V D ( t , f ) = {\int }_{- ∞}^{∞} x ( t + \frac{τ}{2} ) x * ( t - \frac{τ}{2} ) {e}^{- j 2 π f τ} d τ$$

where x(t) is the signal and x*(t) is its complex conjugate. Here, t represents time, f represents frequency, and t is the time lag parameter. This method exhibits high resolution but suffers from cross-term interference when multiple frequency components are present. It has high time-frequency resolution and preserves the signal's energy distribution. However, it also has significant cross-term interference and is difficult to interpret for multicomponent signals.

The Short-Time Fourier Transform (STFT) provides a time-frequency representation of a signal by dividing it into short segments and computing the Fourier transform of each segment. This method is effective for signals with slowly varying frequency components. The STFT is expressed as:

$$S T F T ( t , f ) = {\int }_{- ∞}^{∞} x ( τ ) ω ( τ - t ) {e}^{- j 2 π f τ} d τ$$

where w(τ) is a window function that defines the signal segment to be analyzed. In this equation, t is the center of the window, f is the frequency, and τ is the integration variable.

The choice of window function and its length determines the tradeoff between time and frequency resolution. This method is simple and widely used, clearly representing how frequency components evolve over time. However, it involves a tradeoff between time and frequency resolution and may miss finer details.

The Choi-Williams Distribution (CWD) employs an exponential kernel to reduce interference terms, providing a clearer time-frequency representation of signals with multiple components. The CWD is given by:

$$C W D ( t , f ) = {\int }_{- ∞}^{∞} {\int }_{- ∞}^{∞} x ( u + \frac{τ}{2} ) x * ( u - \frac{τ}{2} ) {e}^{- j 2 π f τ} {e}^{- σ {τ}^{2}} d τ du$$

where σ is a smoothing parameter that controls the reduction of interference terms. Here, t represents time, f represents frequency, u is an intermediate time variable, and τ is the time lag parameter. This method offers balanced time and frequency resolution with reduced cross-terms. However, it results in a less sharp representation, and finer details may be lost.

The Zhao-Atlas-Marks Distribution (ZAMD) utilizes a cone-shaped kernel to improve time-frequency representation by effectively handling cross-terms and maintaining good resolution. The ZAMD is expressed as:

$$Z A M D ( t , f ) = {\int }_{- ∞}^{∞} {\int }_{- ∞}^{∞} x ( u + \frac{τ}{2} ) x * ( u - \frac{τ}{2} ) {e}^{- j 2 π f τ} {K}_{Z A M D} ( θ , τ ) d τ du$$

where K_{ZAMD}(θ,τ) is a cone-shaped kernel defined as:

$${K}_{Z A M D} ( θ , τ ) = \{ \begin{matrix}exp ( - \frac{{θ}^{2}}{2 {σ}^{2}} ) & if \vert θ \vert \leq Θ \\ 0 & otherwise\end{matrix} .$$

In these equations, θ represents the angle parameter, σ is a smoothing parameter, and Θ defines the cone's angular width. This method offers good cross-term suppression but may overly smooth the signal representation. It provides good cross-term suppression. However, it results in an overly smoothed representation and offers less clarity in both the time and frequency domains.

The Born-Jordan Distribution (BJD) is a quadratic TFD that applies a sinc kernel to the WVD, reducing cross-terms and enhancing the resolution of signal components. The BJD is given by:

$$B J D ( t , f ) = {\int }_{- ∞}^{∞} W V D ( t , v ) sinc ( v - f ) d v .$$

This smoothing reduces cross-terms but can also blur important details. It reduces cross-term interference compared to the WVD. However, it still displays cross-term interference and offers less clarity in the representation.

The Cheriet-Belouchrani (CB) Kernel TFD utilizes a kernel with compact support to reduce cross-terms and improve the time-frequency representation. The CB kernel is defined by its control parameters, which determine the width and support of the kernel. The CB TFD is expressed as:

$$C B ( t , f ) = \int \int x ( u + \frac{τ}{2} ) x * ( u - \frac{τ}{2} ) {e}^{- j 2 π f τ} {K}_{C B} ( θ , τ ) d τ du$$

where K_{CB}(θ,τ) is given by:

$${K}_{CB} ( θ , τ ) = \{ \begin{matrix}1 & if \vert θ \vert \leq Θ and \vert τ \vert \leq T \\ 0 & otherwise\end{matrix} .$$

In these equations, θ and τ are time and frequency lag parameters, Θ is the time support parameter, and T is the frequency support parameter.

The choice of kernel determines the level of smoothing and cross-term suppression. This method provides a smoother representation with reduced noise and artifacts. However, it has less distinct frequency resolution and is not as sharp as needed for detailed analysis.

The Separable Kernel Compact Support (SKCS) TFD uses a separable kernel to reduce computational complexity while maintaining good time-frequency resolution. The SKCS TFD is described by:

$$S K C S ( t , f ) = \int \int x ( u + \frac{τ}{2} ) x * ( u - \frac{τ}{2} ) {e}^{- j 2 π f τ} {K}_{S K C S} ( θ , τ ) d τ du$$

where K_{SKCS}(θ,τ) is given by: K_{SKCS}(θ,τ)=k₁(θ)k₂(τ) with k₁(θ) and k₂(τ) being one-dimensional compact support kernels. In this formulation, θ is the angular parameter and t is the time lag. This method simplifies the kernel design but may sacrifice some resolution. It benefits from a simplified kernel design. However, it results in less sharpness in frequency resolution and makes it difficult to discern finer details.

The Polynomial Kernel Compact Support (PKCS) TFD employs a polynomial kernel with compact support to balance time-frequency resolution and computational efficiency. The PKCS TFD is formulated as:

$$P K C S ( t , f ) = \int \int x ( u + \frac{τ}{2} ) x * ( u - \frac{τ}{2} ) {e}^{- j 2 π f τ} {K}_{P K C S} ( θ , τ ) d τ du$$

where K_{PKCS}(θ,τ) is given by:

$${K}_{P K C S} ( θ , τ ) = \{ \begin{matrix}{( 1 - \frac{{θ}^{2}}{{T}^{2}} )}^{m} {( 1 - \frac{{τ}^{2}}{{T}^{2}} )}^{n} & if \vert θ \vert \leq T \& \leq T \\ 0 & otherwise\end{matrix} .$$

The parameters T, m, and n define the support and polynomial order of the kernel. Here, θ is the angular parameter, τ is the time lag, T is the support parameter, and m and n are polynomial orders. This method offers a balanced representation with reduced cross-term interference. However, the representation is relatively smooth, lacking sharpness.

In summary, each of these TFDs has unique characteristics and is suitable for different types of nonstationary signal analysis. The choice of TFD and its parameters depends on the specific application and the nature of the analyzed signal.

The Zoom algorithm is a powerful method for time-frequency analysis of nonstationary signals. By combining windowing, Fast Fourier Transform (FFT), spectral smoothing, convolution, and minimum smart thresholding, it achieves high-resolution spectral representations with minimized noise and artifacts. This method is particularly useful for applications requiring precise spectral analysis, such as communications, biomedical signal processing, and audio analysis. The detailed mathematical analysis presented here elucidates the underlying principles and effectiveness of the Zoom algorithm in achieving superior time-frequency resolution. This section provides a detailed mathematical analysis of each step in the Zoom algorithm.

Signal Windowing: Windowing is essential for analyzing nonstationary signals. It involves segmenting the signal into overlapping windows to capture local frequency content over time. The windowed segment of the signal x(n) is defined as: xₖ(n)=x(n+kS)*w(n) where x(n) represents the original signal, k is the window index, S is the step size indicating how much to shift the window for the next segment, and w(n) is the window function applied to taper the edges of the segment to zero, thereby reducing spectral leakage.

The window function w(n) is typically chosen to be smooth and symmetric to ensure gradual transitions at the edges of each window. This minimizes discontinuities at the boundaries, reducing spectral leakage, which is spreading spectral energy from the true frequency components to neighboring frequencies. Common window functions include the Hamming and Hanning windows, mathematically defined as:

$${w}_{Hamming} ( n ) = 0.54 - 0 \text{.46} cos ( \frac{2 π n}{W - 1} ) {w}_{Hamming} ( n ) = 0.5 ( 1 - cos ( \frac{2 π n}{W - 1} ) ) .$$

Fast Fourier Transform (FFT): The FFT transforms the time-domain signal within each window into the frequency domain, revealing the signal's frequency content at each window position. For the kth windowed segment xₖ(n), the FFT is defined as:

$${X}_{k} ( f ) = {\sum }_{n = 0}^{W - 1} {x}_{k} ( n ) {e}^{- j 2 π fn / W}$$

where Xₖ(f) represents the frequency spectrum of the kth windowed segment, and W is the window size. The FFT converts the discrete time-domain signal into a discrete frequency-domain representation. This transformation is computationally efficient, leveraging the symmetry and periodicity properties of the Discrete Fourier Transform (DFT).

Spectral Smoothing: Spectral smoothing is applied to the FFT results to reduce noise and emphasize significant spectral components. The smoothed spectrum Xₖ(f) is computed using a weighted average of the current and previous spectra.

The recursive equation ensures that each spectral estimate incorporates information from previous windows, resulting in a smoother spectral representation that reduces random fluctuations (noise) while preserving the underlying signal characteristics.

Minimum Smart Threshold: To further refine the spectral representation and suppress noise, a smart minimum threshold c-smart minimum is applied. This technique sets a minimum threshold relative to the maximum value in each spectrum, ensuring only significant components are retained. This step helps reduce artifacts by eliminating spectral components that fall below a certain fraction of the maximum value in each windowed segment. It ensures that only significant spectral features are preserved, enhancing the clarity of the time-frequency representation.

Reconstruction and Result: The final time-frequency representation is reconstructed by combining the processed spectra from all windows. The reconstructed signal R(n) in the frequency domain is obtained by summing the contributions from each windowed segment. The reconstructed signal R(n) represents a comprehensive time-frequency analysis, capturing the evolution of the signal's frequency content over time with high resolution.

Integration of Convolution Transform: To further refine the time-frequency representation, the proposed technology applies the Convolution Transform. The Convolution Transform utilizes a specified kernel, such as a Gaussian kernel, to smooth and enhance the features of the signal.

This approach leverages the properties of the convolution operation to refine the reconstructed signal, ensuring high-resolution time-frequency analysis of nonstationary signals.

To quantitatively assess the performance of this developed TFD, the proposed technology applies the Boashash-Sucic Normalized Instantaneous Resolution. This metric evaluates the resolution of the TED by comparing the energy concentration in the main lobes, side lobes, and cross terms of the signal components. A well-performing TFD will exhibit high energy concentration in the main lobes with minimal energy spread in the side lobes and cross terms. The Boashash-Sucic performance measure, ρ, is defined as:

$$ρ = \frac{{\sum }_{i = 1}^{N} {\vert T F D ( {τ}_{i} , {f}_{i} ) \vert}^{2}}{\begin{matrix}{\sum }_{i = 1}^{N} {\vert T F {D}_{main} ( {τ}_{i} , {f}_{i} ) \vert}^{2} + {\sum }_{i = 1}^{N} {\vert T F {D}_{side} ( {τ}_{i} , {f}_{i} ) \vert}^{2} + \\ {\sum }_{i = 1}^{N} {\vert T F {D}_{cross} ( {τ}_{i} , {f}_{i} ) \vert}^{2}\end{matrix}} ,$$

where: TFDₘₐᵢₙ represents the average amplitude of the main lobes, TFD_{side} represents the average amplitude of the side lobes, and TFD cross represents the average amplitude of the cross terms. The numerator in this equation represents the sum of the squared amplitudes of the TED at the main lobe positions, while the denominator is the total sum of the squared amplitudes of the TED, including main lobes, side lobes, and cross terms. A higher value of p indicates a better-performing TFD with greater resolution and minimal interference.

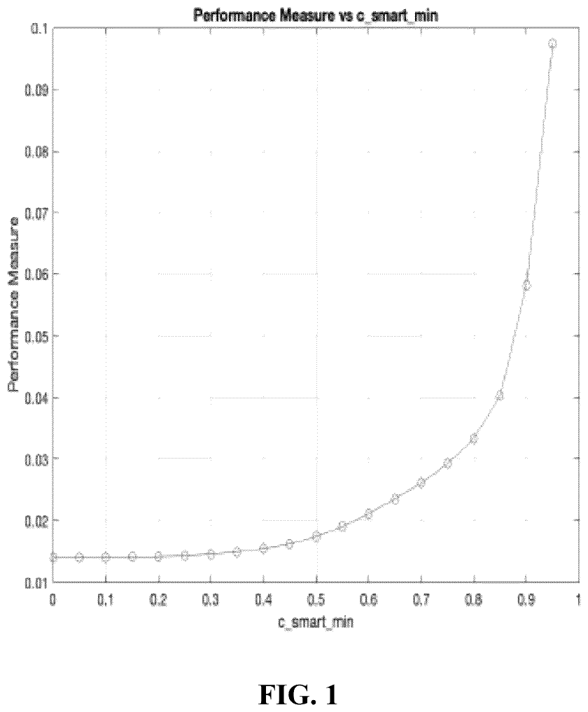

This developed Time-frequency Distribution (TFD) performance was evaluated using the Boashash-Sucic Normalized Instantaneous Resolution Performance Measure across various smart minimum values. FIG. 1 shows the variation of the performance against the smart minimum values; results indicate a clear trend of increasing performance with higher smart minimum (Sₘᵢₙ) values. Initially, for Sₘᵢₙ values up to 0.35, the performance measure remains relatively low, around 0.014, suggesting limited improvement in distinguishing the main-lobe amplitude from sidelobes and cross-terms. As the Sₘᵢₙ value increases, there is a noticeable enhancement in performance. Starting from Sₘᵢₙ=0.4, the performance measure rises more significantly, reaching 0.015. This upward trend continues, with a marked increase observed at Sₘᵢₙ=0.6, where the performance measure jumps to 0.021. The highest performance measure is achieved at Sₘᵢₙ=0.95, with a value of 0.097. This indicates that the TFD is most effective in concentrating energy around the signal components' instantaneous frequencies while minimizing interference from side lobes and cross-terms at this smart minimum value. Overall, the results demonstrate that higher Sₘᵢₙ values significantly enhance the quality of the time-frequency distribution, making this TFD more effective for signal analysis.

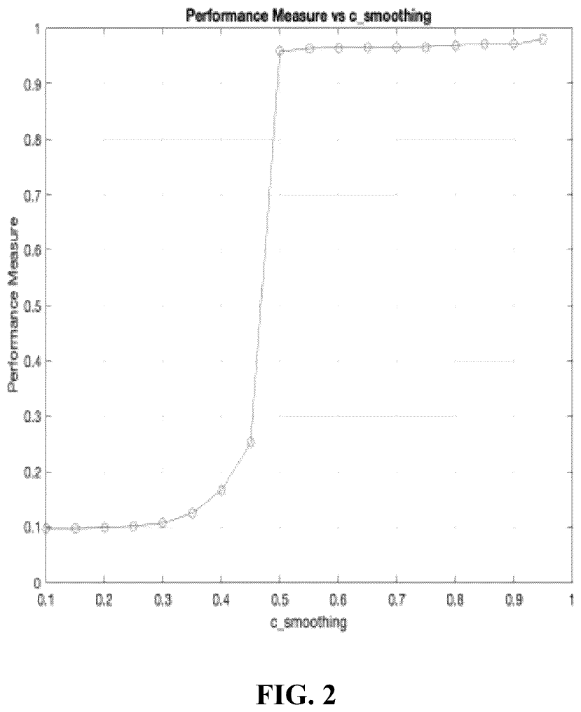

The performance of this developed TFD was assessed using the Boashash-Sucic Normalized Instantaneous Resolution Performance Measure across various smoothing values (c-smoothing). FIG. 2 shows a clear trend of increasing performance with higher c-smoothing values. Initially, for c-smoothing values up to 0.35, the performance measure remains relatively low, around 0.097, indicating limited improvement in distinguishing the main-lobe amplitude from sidelobes and cross-terms. However, as c-smoothing increases, there is a significant enhancement in performance. At c-smoothing=0.4, the performance measure rises noticeably to 0.17, demonstrating better filtering capability. A substantial increase is observed starting at c-smoothing=0.5, where the performance measure jumps to 0.96, indicating a marked improvement in the TFD's ability to concentrate energy around the instantaneous frequencies of signal components while minimizing sidelobe and cross-term interference. The highest performance measure is recorded at c-smoothing=0.95, with a value of 0.98, signifying optimal filtering performance. These findings highlight that higher c-smoothing values significantly enhance the quality of the time-frequency distribution, making this TFD more effective for signal analysis.

Table 1 presents the performance analysis of this developed Time-frequency Distribution (TFD) applied to various signal types, using two different sets of parameters: c-smoothing=0.5, Smin=0.995 and c-smoothing=0.5, Smin=0.95. The performance metrics indicate that the TED with a higher smart minimum value (0.995) consistently achieves superior performance across all signal types, as evidenced by higher performance scores compared to the TFD with a smart minimum value of 0.95. For instance, the TED with Smin=0.995 demonstrates a performance measure of 0.99652 for the chirp signal, whereas the same signal exhibits a measure of 0.95837 with Smin=0.95. Similar trends are observed for other signals such as the sum of nonparallel nonintersecting chirps and intersecting sinusoidal FM signals (0.99 vs. 0.96), and the sum of two sinusoidal FM signals and two chirp signals (0.99 vs. 0.92). These results underscore the effectiveness of using a higher smart minimum value to enhance the TFD's ability to concentrate energy around the signal components' instantaneous frequencies while minimizing interference from side lobes and cross-terms, thus providing clearer and more accurate signal representations. This improvement is particularly significant in complex signals where the energy concentration and resolution are crucial for accurate interpretation.

TABLE 1

| | | c = |
|---|---|---|
| | c_smoothing = | smoothing = |
| | 0.5, S_min = | 0.5, S_min = |
| Signal Type | 0.995 | 0.95 |
| Sum of Nonparallel Non- | 0.9959 | 0.9605 |
| intersecting Chirps and | | |
| Intersecting Sinusoidal FM | | |
| Signals | | |
| Chirp | 0.9965 | 0.9584 |
| Sum of Two Sinusoidal FM | 0.9865 | 0.9191 |
| Signals and Two Chirp | | |
| Signals | | |
| Two Crossing Linear FM | 0.9939 | 0.9546 |
| Signals | | |
| Two Parallel Linear FM | 0.9946 | 0.9576 |
| Signals | | |
| Linear Test | 0.9957 | 0.9614 |
| Mixed Test 1 | 0.9957 | 0.9611 |
| Sine Test 2 | 0.9959 | 0.9625 |
| Step | 0.9958 | 0.9611 |
| Sawtooth | 0.9958 | 0.9616 |

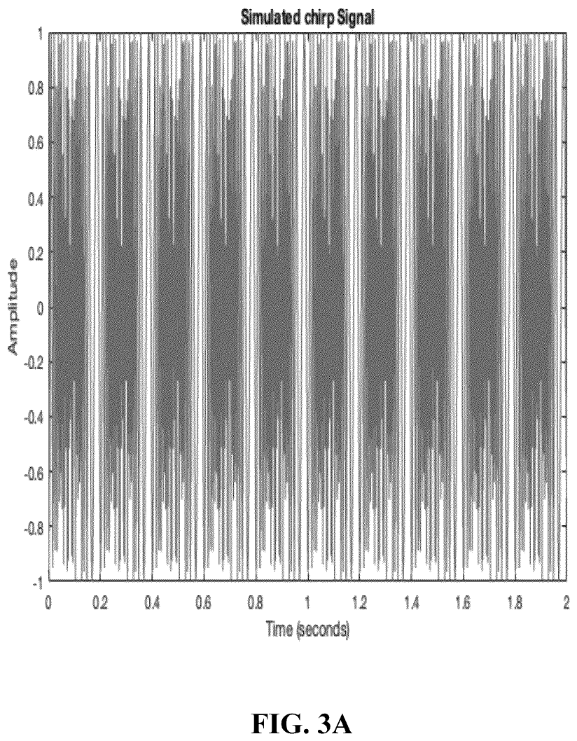

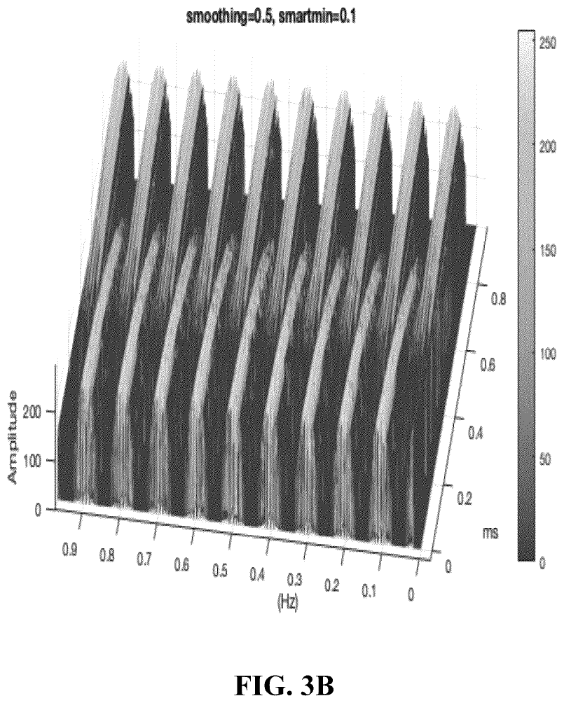

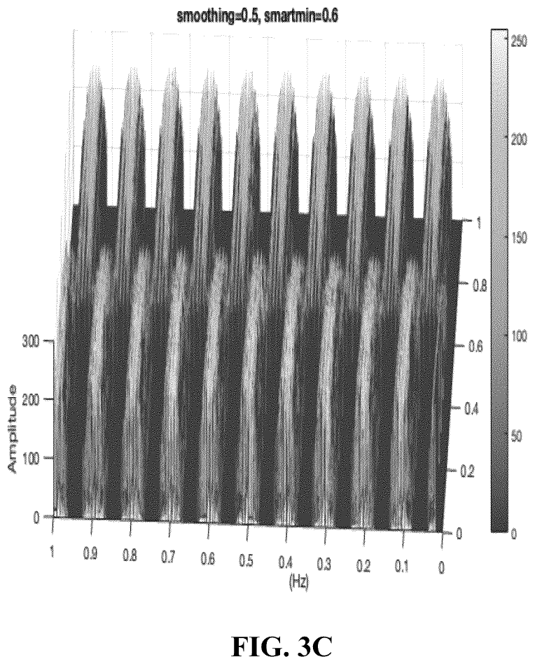

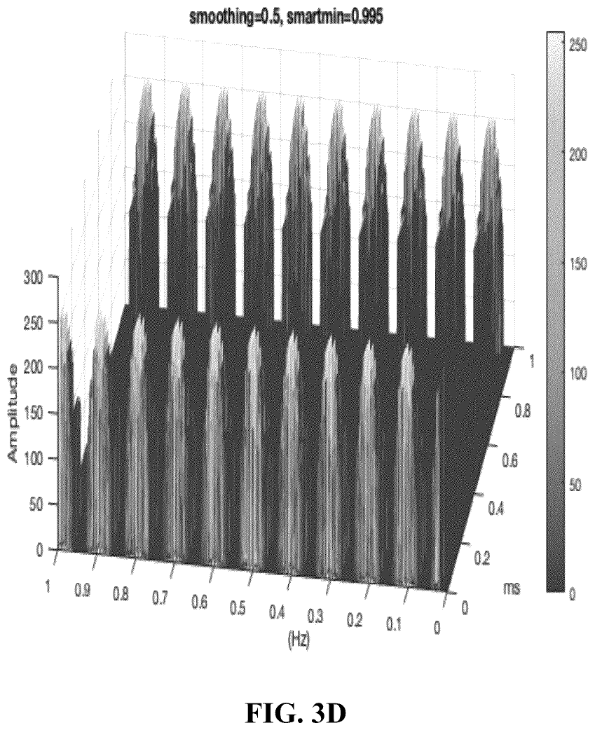

FIGS. 3A to 3D illustrate the application of this developed Time-frequency Distribution (TFD) to a chirp signal, demonstrating the effects of varying smart minimum values. The chirp signal, characterized by a frequency that increases linearly over time, is shown in the top subplot. The subsequent subplots present the time-frequency representations obtained with different combinations of the smoothing parameter (fixed at 0.5) and smart minimum values ranging from 0 to 0.995. In the initial subplots with lower smart minimum values (e.g., 0.05 to 0.35), the time-frequency representation exhibits noticeable noise and artifacts, indicating limited effectiveness in energy concentration around the instantaneous frequency of the chirp signal. These lower values result in a less distinct representation of the chirp signal's frequency modulation, with visible interference from side lobes and cross-terms. As the smart minimum value increases to around 0.4 and above, there is a gradual improvement in the clarity and resolution of the time-frequency representation. However, the changes are not drastic, and the performance enhancement is incremental.

The time-frequency representation becomes somewhat cleaner for smart minimum values such as 0.4 and 0.5, with reduced noise and a more concentrated energy alignment along the chirp signal's frequency trajectory. Further increasing the smart minimum value to 0.6 and beyond, up to 0.95, continues to show slight improvements in the TFD's performance. The time-frequency representations for these higher values exhibit a more defined and smoother portrayal of the chirp signal's linear frequency increase. Nevertheless, the performance gains are modest, and the TFD results with smart minimum values in the range of 0.7 to 0.95 show only minor refinements in reducing artifacts and enhancing resolution. Overall, FIGS. 3A to 3D indicate that while increasing the smart minimum value does lead to better time-frequency representations, the improvements are gradual and not substantial. The highest performance is observed at a smart minimum value of 0.95, where the TED achieves the best balance in minimizing side lobes and cross-terms. However, the incremental nature of the performance enhancement suggests that optimizing the smart minimum value should be considered in conjunction with other parameters to achieve the most effective time-frequency analysis.

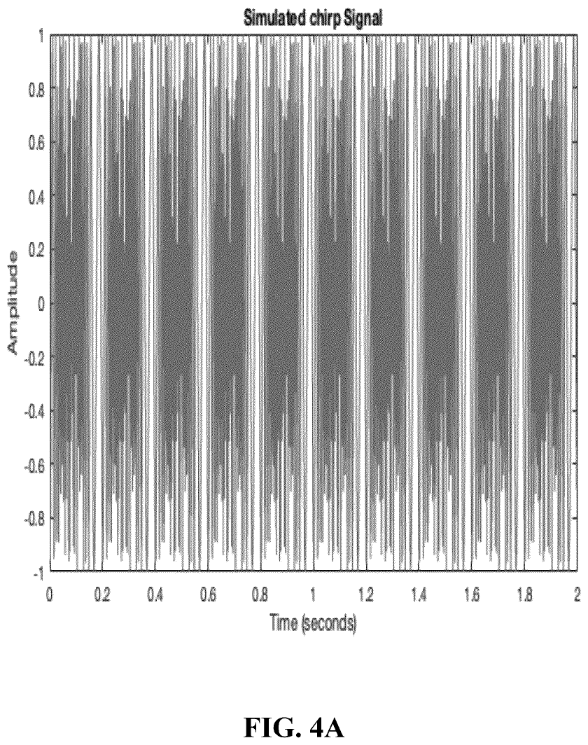

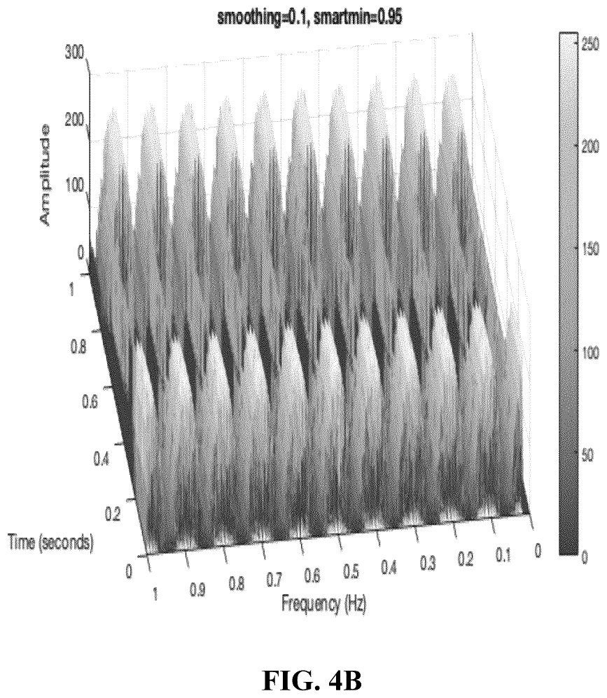

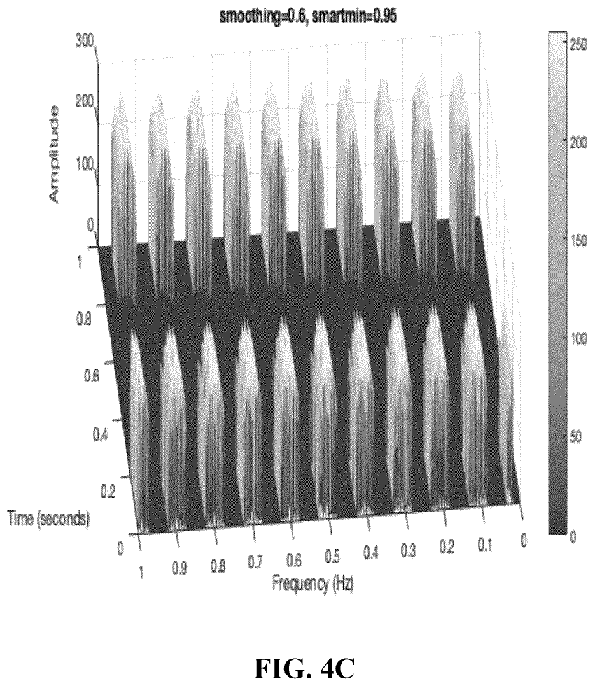

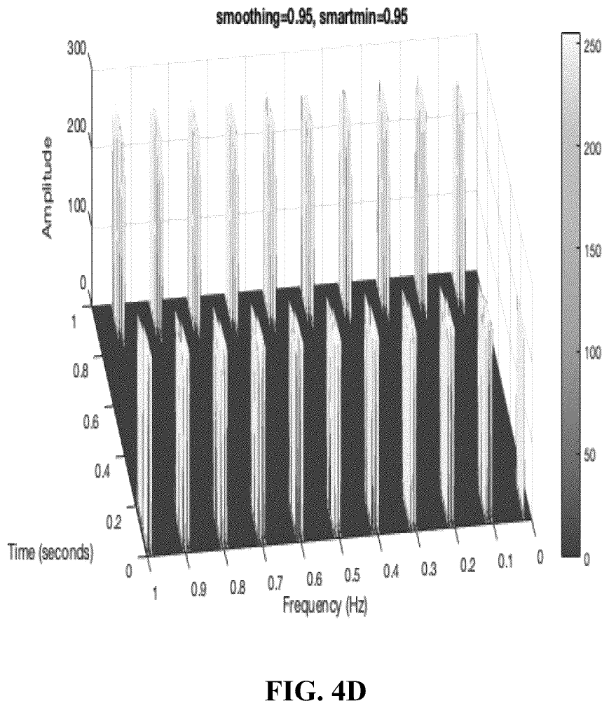

FIGS. 4A to 4D demonstrate the application of this developed Time-frequency Distribution (TFD) to a chirp signal, illustrating the impact of varying smoothing values while maintaining a fixed smart minimum value of 0.95. The top subplot shows the chirp signal with its linearly increasing frequency over time, followed by subplots displaying time-frequency representations for smoothing values ranging from 0.1 to 0.95. Lower smoothing values (0.1 to 0.35) result in noisy time-frequency representations with significant artifacts, indicating limited effectiveness in concentrating energy around the instantaneous frequency. As the smoothing value increases to 0.4 and above, the clarity and resolution improve markedly, with reduced noise and better energy concentration along the chirp signal's frequency trajectory. This enhancement is reflected in the performance measure, indicating superior filtering capability. Higher smoothing values (0.5 to 0.95) further improve the TFD's performance, yielding well-defined and smooth representations of the chirp signal's linear frequency progression and effectively suppressing sidelobes and cross-terms. Overall, higher smoothing values significantly enhance the quality of the time-frequency distribution, leading to clearer and more accurate signal representations and underscoring the importance of optimizing the smoothing parameter for optimal time-frequency analysis performance.

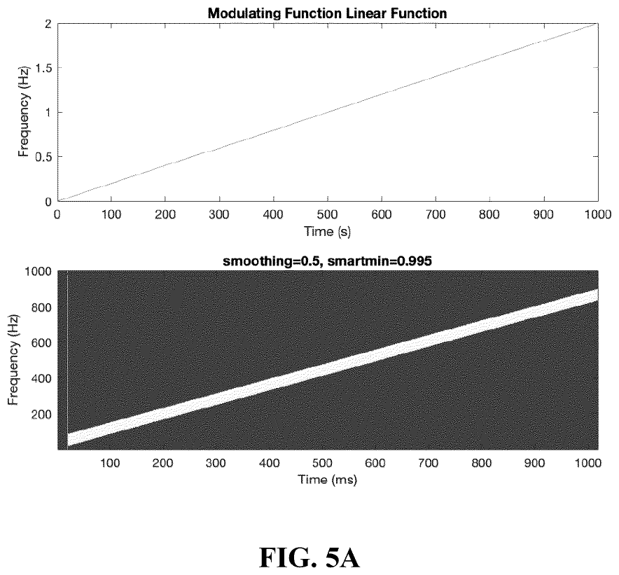

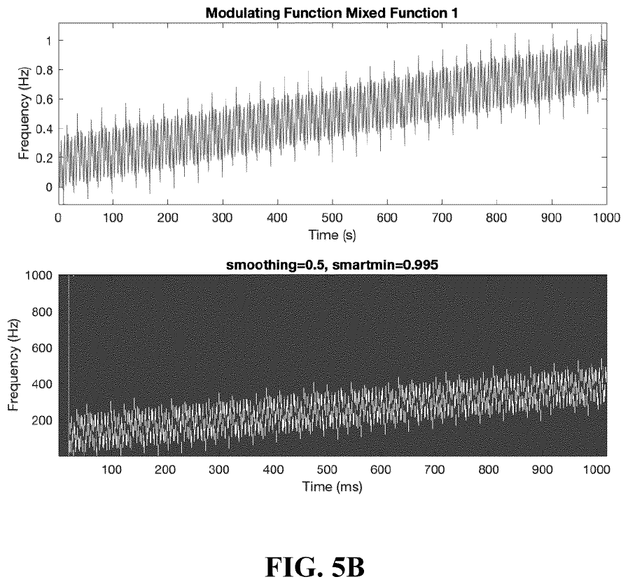

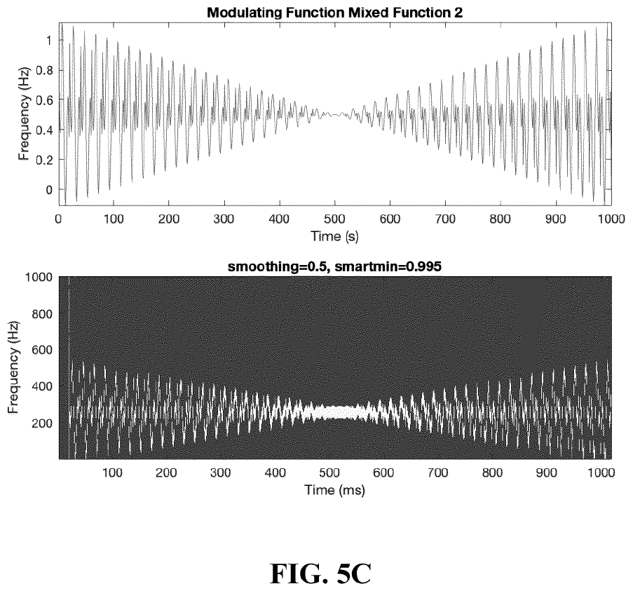

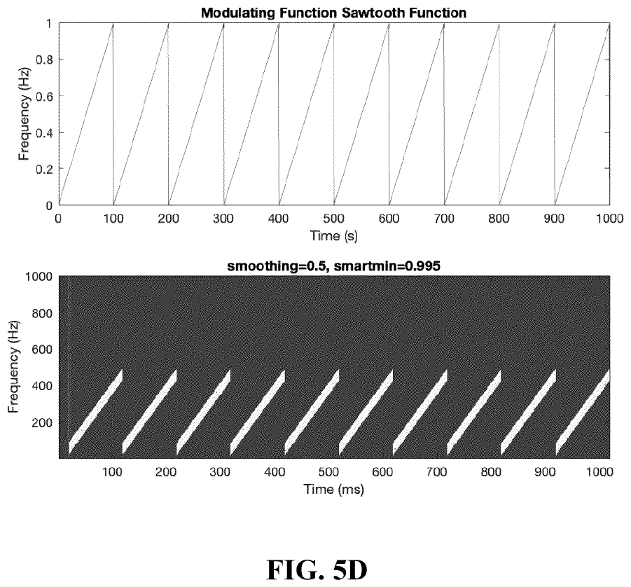

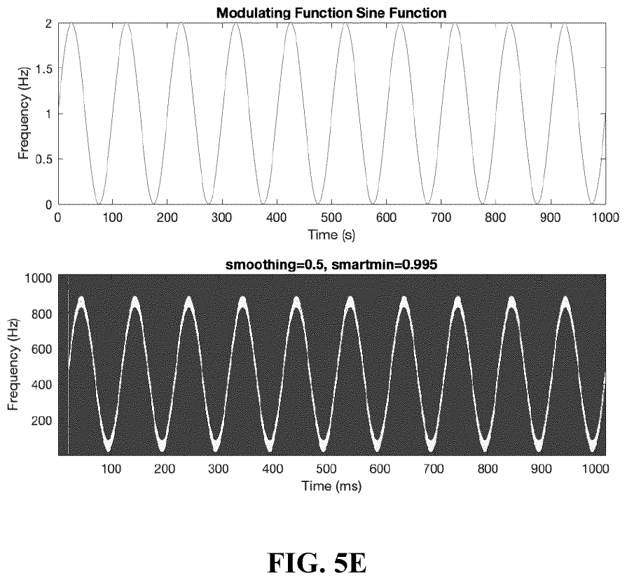

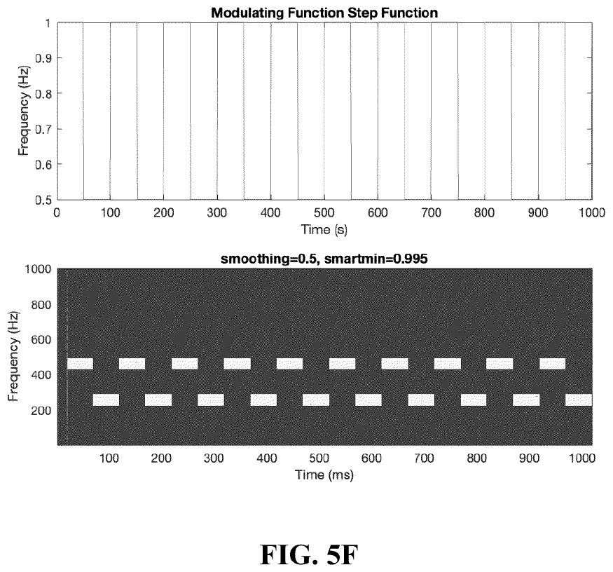

FIGS. 5A to 5F showcase the efficacy of this developed Time-frequency Distribution (TFD) applied to various standard signal types, including linear, mixed, sawtooth, sine, and step functions. The TED results are presented using a smoothing parameter of 0.5 and a smart minimum value of 0.995. Each accurately captures the abrupt transitions, presenting discrete frequency content blocking time-frequency representation (bottom), illustrating the TFD's capability in capturing signal characteristics with high resolution.

For the linear function (FIG. 5A), this TFD accurately delineates the constant rate of frequency increment over time, represented by a sharp linear trajectory in the time-frequency domain. This outcome demonstrates the TFD's proficiency in resolving linear chirp signals, preserving the main-lobe integrity while minimizing sidelobe artifacts, which is critical for maintaining high time-frequency localization.

The mixed function 1 (FIG. 5B) exhibits a composite structure with varying frequency components. The TED effectively resolves these components, offering a detailed time-frequency depiction that distinguishes the individual frequency elements over time. This indicates the robustness of this TFD in handling multicomponent signals, ensuring clear separation and accurate representation of overlapping frequencies.

In the case of mixed function 2 (FIG. 5C), characterized by frequency modulation, the TFD captures the dynamic frequency changes with high fidelity. The resulting time-frequency representation highlights the TFD's ability to process nonlinear frequency modulations, precisely tracking instantaneous frequency variations essential for complex signal analysis.

The sawtooth function (FIG. 5D) features periodic frequency ramps. The TFD output clearly displays these periodic jumps, maintaining distinct transitions between successive frequency components. This illustrates the TFD's capability to manage signals with abrupt frequency changes, ensuring sharp delineation of frequency transitions without smearing, which is pivotal for accurate signal characterization.

For the sine function (FIG. 5E), the TFD produces a smooth and continuous representation of the periodic oscillations. The main lobe is distinctly defined with minimal sidelobe interference, highlighting the TFD's effectiveness in representing harmonic signals with high spectral purity, which is crucial for applications requiring precise frequency resolution.

Lastly, the step function (FIG. 5F) demonstrates the TFD's performance with signals exhibiting sudden frequency changes. The TED captures the abrupt transitions accurately, presenting discrete blocks of frequency content. This underscores the TFD's strength in resolving signals with instantaneous frequency shifts, ensuring clear and distinct frequency component representation.

Overall, FIGS. 5A to 5F demonstrate that this developed TFD, with a smoothing parameter of 0.5 and a smart minimum value of 0.995, provides superior time-frequency representations across various signal types. These parameters effectively balance the tradeoff between time and frequency resolution, preserving the main lobe structure while minimizing the impact of side lobes and cross-terms. This results in high-resolution time-frequency distributions essential for detailed signal analysis.

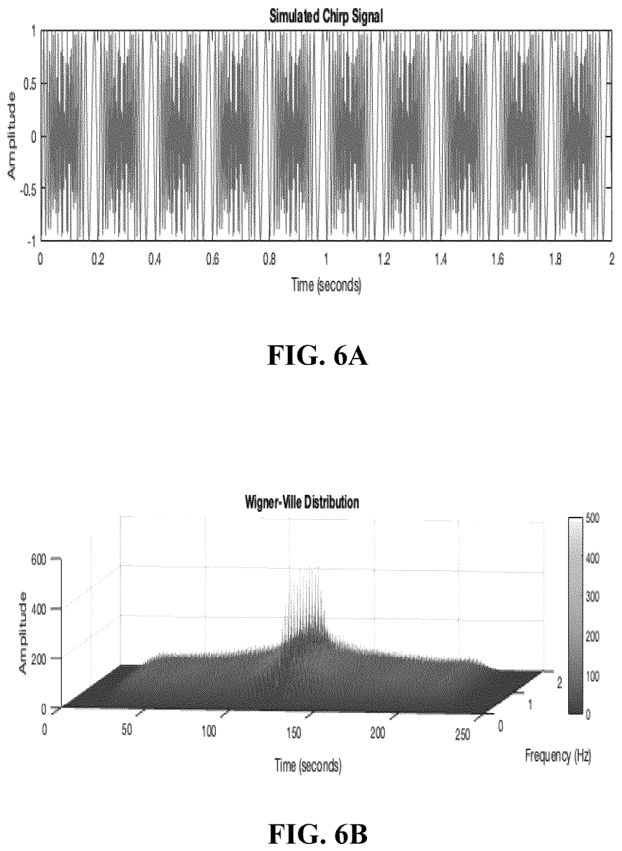

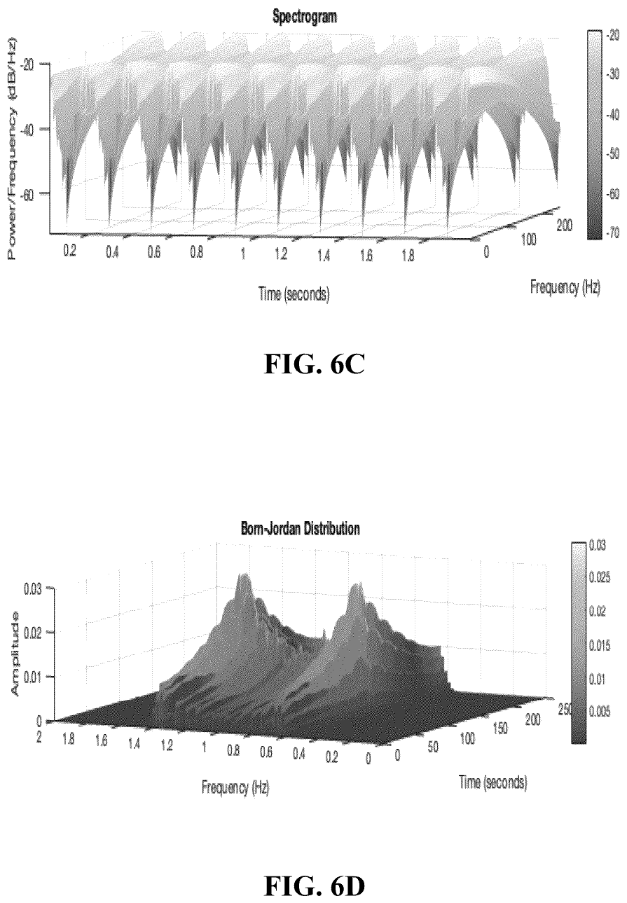

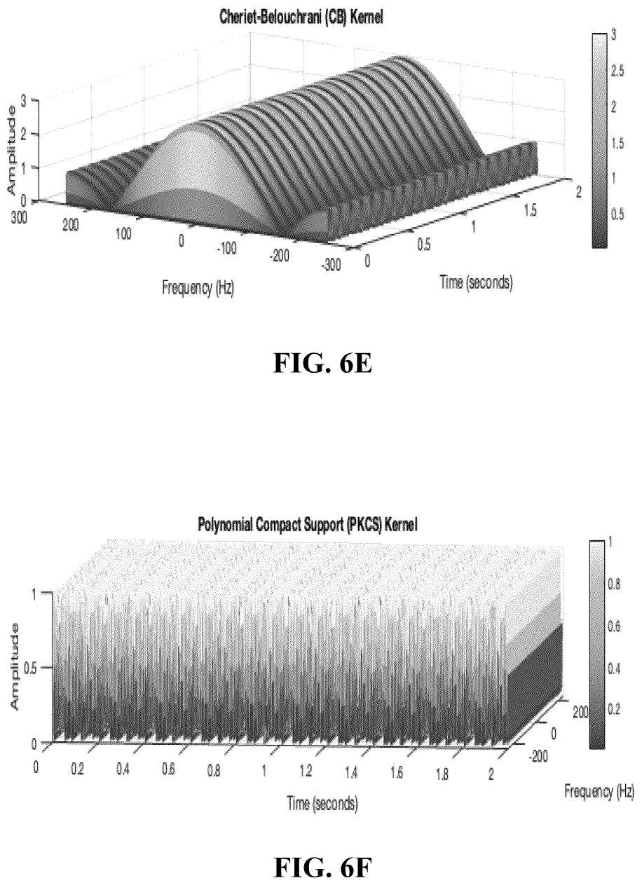

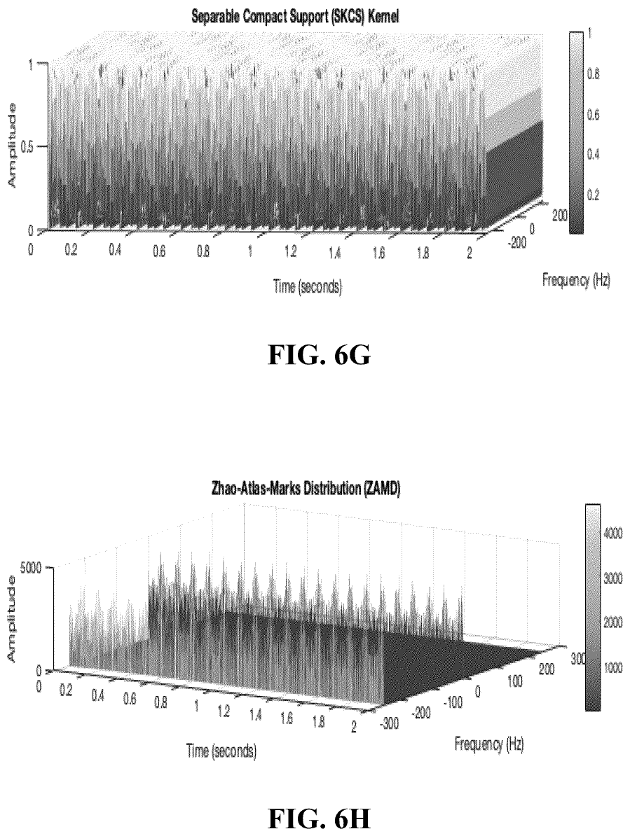

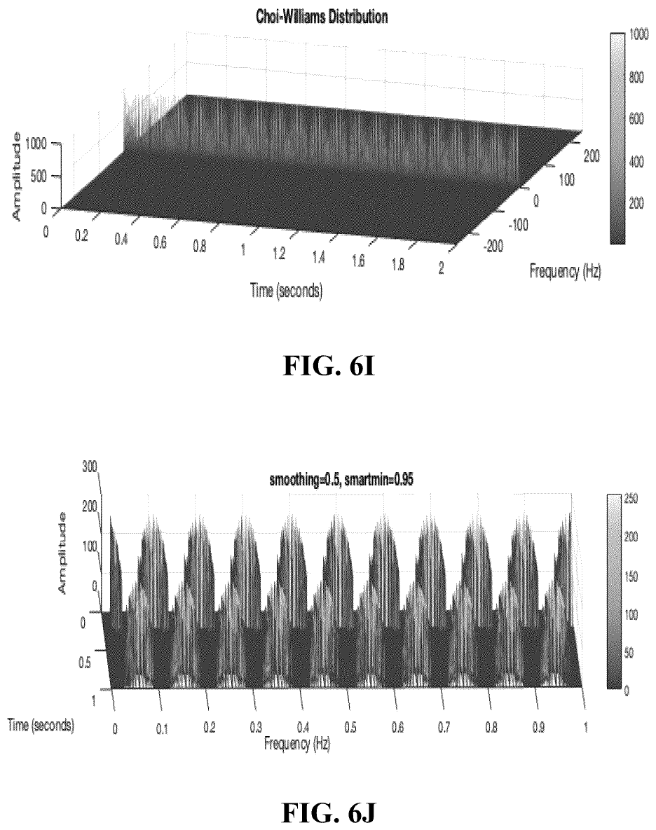

FIGS. 6A to 6J presents a comparative analysis of various Time-frequency Distributions (TFDs) applied to a chirp signal, including the Wigner-Ville Distribution (WVD), Short-Time Fourier Transform (STFT), Born-Jordan Distribution (BJD), Cheriet-Belouchrani (CB) Kernel TFD, Polynomial Kernel Compact Support (PKCS) TFD, Separable Kernel Compact Support (SKCS) TFD, Choi-Williams Distribution (CWD), and Zhao-Atlas-Marks Distribution (ZAMD). Each TFD is evaluated for its effectiveness in representing the chirp signal, which increases linearly from 0 Hz to 250 Hz over 2 seconds. The WVD shows high resolution but significant cross-terms, making it difficult to interpret. Using a Hanning window of length 85, the spectrogram provides a clearer representation but sacrifices some frequency resolution, with a power frequency spread visible around the chirp. The BJD reduces cross-terms with a sinc kernel, yielding a cleaner result than WVD, although minor artifacts remain. The CB TFD, with parameters D=M/B=4 and A=eC=1.44, provides a compact support distribution that minimizes cross-terms and enhances midfrequency range clarity. The SKCS TFD maintains good time-frequency resolution with minimal interference, demonstrating an effective separable kernel design. The PKCS TFD, using polynomial orders m and n and support parameter T, effectively suppresses cross-terms, providing a sharp representation. The ZAMD, with a cone-shaped kernel (α=0.8), offers an improved representation with minor artifacts at lower frequencies. Using an exponential kernel with σ=0.45, the CWD reduces interference terms significantly, achieving high clarity. Finally, this developed TFD, with a smoothing value of 0.5 and a smart minimum value of 0.95, outperforms traditional TFDs, offering a clear and well-defined chirp representation with minimal cross-terms and high resolution. Specifically, this method shows a significant reduction in cross-term artifacts, maintaining the integrity of the chirp signal across its frequency range. The clear depiction of the frequency modulation over time demonstrates the effectiveness of this TFD parameters in balancing the tradeoff between time and frequency resolution. This comparative study highlights this TFD's superior performance in preserving the signal's main lobe structure while minimizing the impact of side lobes and cross-terms, making it a valuable tool for advanced signal analysis.

Table 2 presents the optimization results for selecting Time-frequency Distributions (TFDs) applied to the chirps test. The performance measure p indicates the effectiveness of each TFD in concentrating energy around the signal components' instantaneous frequencies while minimizing interference from side lobes and cross-terms. The Wigner-Ville Distribution (WVD) shows a relatively low-performance measure of 0.67, indicating significant interference. The Spectrogram with a Hanning window (L=85) performs better with a ρ of 0.84, demonstrating improved energy concentration. The Born-Jordan Distribution (BJD) achieves a ρ of 0.72, while the Choi-Williams Distribution (CWD) with σ=0.45 shows a comparable performance with a ρ of 0.73. The Zhao-Atlas-Marks Distribution (ZAMD) with α=0.8 has a ρ of 0.68, slightly better than WVD but still below other methods. Cheriet-Belouchrani (CB) TFD, Separable Cheriet-Belouchrani (SCB) TFD, and Polynomial Cheriet-Belouchrani (PCB) TFD show high-performance measures of 0.87, 0.87, and 0.86, respectively, highlighting their efficiency in time-frequency analysis. This developed TFD method, with parameters (c smoothing)=0.95 and (S min)=0.995, achieves the highest performance measure of 0.98. This indicates a significant improvement over existing methods, demonstrating superior capability in accurately representing the signal's time-frequency characteristics while effectively minimizing interference and cross-terms. This comparison underscores the effectiveness of this TFD method in providing a clearer and more precise analysis of nonstationary signals compared to traditional and contemporary TFDs.

TABLE 2

| TFD | Optimal Kernel Parameters | ρ |
|---|---|---|
| WVD | N/A | 0.67 |
| Spectrogram | Hanning, L = 85 | 0.84 |
| BJD | N/A | 0.72 |
| CWD | σ = 0.45 | 0.73 |
| ZAMD | α = 0.8 | 0.68 |
| CB TFD | D = M/B = 4, A = e^{C} = 1.44 | 0.87 |
| SCB TFD | D = M/b = 5, A = e^{C} = 2.1 | 0.87 |
| PCB TFD | λ = 22, γ = 2 | 0.86 |
| Present Disclosure | c_smoothing = 0.95, S_min = 0.995 | 0.98 |

The performance of the Time-Frequency Distribution (TFD) is evaluated using the Boashash performance measure, which is a standard metric for assessing the quality of TFDs in terms of resolution and cross-term suppression. The performance comparison reveals that this TFD method significantly outperforms existing methods. The S-method proposed by literature achieved a performance measure of 0.87. While effective, this method is limited by its ability to manage cross-terms and resolution. In 2021, literature introduced the Regional Adaptive Compact Kernel Distribution (RACKD), which improved the performance measure to 0.92 by using a signal-dependent kernel that adapts to the signal's characteristics, effectively reducing cross-term interference. Literature further enhanced this approach with the Adaptive Compact Kernel Distribution (ACKD), achieving a performance measure of 0.93. This method utilizes an adaptive mechanism to finetune the kernel, providing better resolution and cross-term suppression.

More recently, literature proposed an optimal TFD method with a performance measure of 0.90. While this method demonstrates significant improvements over earlier techniques, it still falls short of the performance achieved by this TFD method.

This method achieves a superior performance measure of 0.99 using optimal smoothing and smart minimum values, indicating its effectiveness in providing high-resolution time-frequency representations with minimal cross-term interference. This is attributed to this optimized kernel function, which adapts to the specific characteristics of the signal, ensuring better energy concentration and accurate instantaneous frequency estimation. The robustness and reliability of this TFD method across various signal types, including linear chirps, sinusoidal frequency modulated signals, and multicomponent signals, underscore its potential as a valuable tool for complex signal analysis.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A high-resolution time-frequency analysis for nonstationary signals, comprising:
a signal-windowed Fast Fourier Transform; and
a harmonic suppression.

2. The time-frequency analysis of claim 1, wherein the signal-windowed Fast Fourier Transform includes a Hamming window function.

3. The time-frequency analysis of claim 1, wherein the time-frequency analysis comprises spectral smoothing.

4. The time-frequency analysis of claim 3, wherein the spectral smoothing is recursive.

5. The time-frequency analysis of claim 1, wherein the time-frequency analysis comprises convolution.

6. The time-frequency analysis of claim 5, wherein the convolution includes a Gaussian kernel to smooth and enhance the nonstationary signal.

7. The time-frequency analysis of claim 1, wherein the time-frequency analysis comprises minimum smart thresholding.

8. The time-frequency analysis of claim 1, wherein the time-frequency analysis comprises a reconstruction of the time-frequency analysis by combining processed spectra.

9. A method of using a high-resolution time-frequency analysis for nonstationary signals, comprising:
performing a signal-windowed Fast Fourier Transform; and
performing a harmonic suppression.

10. The method of claim 9, wherein performing the signal-windowed Fast Fourier Transform includes performing a Hamming window function.

11. The method of claim 9, wherein the method further comprises performing spectral smoothing.

12. The method of claim 11, wherein performing the spectral smoothing is recursive.

13. The method of claim 9, wherein the method further comprises performing convolution.

14. The method of claim 13, wherein performing convolution includes utilizing a Gaussian kernel to smooth and enhance the nonstationary signal.

15. The method of claim 9, wherein the method further comprises performing minimum smart thresholding.

16. The method of claim 9, wherein the method further comprises reconstructing the time-frequency analysis by combining processed spectra.
